(19) United States
(12) Patent Application Publication
(10) Pub. No.: US 2026/0123211 A1
(43) Pub. Date: Apr. 30, 2026

(54) DISPLAY DEVICE, ELECTRONIC DEVICE, AND METHOD FOR MANUFACTURING DISPLAY DEVICE

(71) Applicant: SAMSUNG DISPLAY CO., LTD., YONGIN-SI (KR)

(72) Inventors: Seung Min LEE, Yongin-si (KR); So Yeon JEONG, Yongin-si (KR); Souk-June HWANG, Yongin-si (KR)

(21) Appl. No.: 19/258,226

(22) Filed: Jul. 2, 2025

(30) Foreign Application Priority Data
Oct. 29, 2024 (KR) 10-2024-0150153

(51) Int. Cl. H10K 59/131; H10K 59/12; H10K 59/95

(52) U.S. Cl. CPC H10K 59/131; H10K 59/1201; H10K 59/95

(57) ABSTRACT

A display device according to an embodiment includes: a substrate including a display area and a non-display area that is adjacent to the display area; a pixel overlapping the display area; a base layer disposed on a first surface of the substrate; and an electrode pad disposed below a surface facing the substrate and overlapping the non-display area, wherein the substrate includes an opening exposing the electrode pad, and a lateral surface of the substrate defining the opening includes recess portions.

### CROSS-REFERENCE TO RELATED APPLICATION

This patent application claims priority under 35 U.S.C. § 119 to Korean Patent Application No. 10-2024-0150153 filed on Oct. 29, 2024, in the Korean Intellectual Property Office, the disclosure of which is incorporated by reference in its entirety herein.

### (a) Technical Field

The present disclosure relates to a display device, an electronic device, and a method for manufacturing a display device.

### (b) Discussion of Related Art

As information technology continues to advance, display devices, which serve as a medium connecting users with information are becoming increasingly important. Accordingly, the adoption of display devices, such as a liquid crystal display devices and organic light emitting display devices, has been on the rise.

In display devices, the bezel refers to the border or frame surrounding the active display area, typically housing electrical connections and peripheral components. Reducing the bezel size is a key design goal in modern electronic devices, as it enables a larger screen-to-body ratio and a more immersive viewing experience. However, current display architectures require electrode pads and components to be positioned near a front surface or an edge of the display panel, limiting how much the bezel can be minimized. Moreover, manufacturing processes that expose these electrode pads can damage the pads or adjacent layers, especially if the materials used are not resistant to etchants. Additionally, physical characteristics of the etched openings can result in poor adhesion during bonding, leading to reliability issues over time. These challenges make it difficult to achieve both narrow bezels and high manufacturing reliability in existing designs.

### SUMMARY

The present disclosure aims to meet design demands by reducing a bezel region of a display device, and preventing damage to electrode pads and surrounding layers during a process for manufacturing the display device.

An embodiment of the present disclosure provides a display device including: a substrate including a display area and a non-display area that is adjacent to the display area; a pixel overlapping the display area; a base layer disposed on a first surface of the substrate; and an electrode pad disposed below a surface of the base layer facing the substrate and overlapping the non-display area, wherein the substrate includes an opening exposing the electrode pad, and a lateral surface of the substrate that defines the opening includes recess portions.

The display device may further include a chip-on-film including a driver for providing electrical signals to the pixel, wherein the electrode pad may be electrically connected to the chip-on-film.

At least a portion of the chip-on-film may overlap the display area.

The chip-on-film may include a connection pad electrically connected to the electrode pad, and may further include an adhesive member disposed between the connection pad and the electrode pad.

The electrode pad may include at least one of tungsten (W), molybdenum (Mo), and chromium (Cr).

The electrode pad may include a first metal layer and a second metal layer, the second metal layer may include at least one of tungsten and chromium, and the opening may expose the second metal layer.

The base layer may include at least one of silicon nitride (SiNₓ), amorphous silicon (a-Si), and silicon oxide (SiOₓ).

The base layer may include a first layer including silicon nitride, a second layer including amorphous silicon, and a third layer including silicon oxide.

The opening may expose a portion of the first layer.

The substrate may further include a second surface facing the first surface and connected to the lateral surface, and a surface roughness of the lateral surface may be greater than a surface roughness of the second surface.

The display device may further include a planarization layer disposed on the base layer and overlapping the non-display area.

The planarization layer may include at least one selected from a group consisting of polyimide, polyamide, acryl resin, benzocyclobutene, and phenol resin.

The display device may further include a sealing layer disposed on the pixel and including a portion overlapping the display area, wherein the planarization layer may be disposed adjacent to the sealing layer.

An embodiment of the present disclosure provides a method for manufacturing a display device including: forming an electrode pad in a non-display area of a substrate; forming a base layer on the electrode pad; forming pixels in a display area of the substrate adjacent to the non-display area; patterning a region of a lower surface of the substrate corresponding to the electrode pad to form a groove overlapping the electrode pad; and etching the lower surface of the substrate, including the groove, to form an opening that exposes the electrode pad.

A lateral surface of the substrate defining the opening may include recess portions.

The electrode pad may include at least one of tungsten (W), molybdenum (Mo), and chromium (Cr).

The forming of the base layer may include forming the first layer including silicon nitride, forming the second layer including amorphous silicon on the first layer, and forming the third layer including silicon oxide on the second layer.

The patterning may include forming the groove extending in a direction in which the electrode pad is aligned and overlapping the electrode pad by using a circular blade.

A depth of the groove may be about 0.5 to 0.6 times the thickness of the substrate.

The etching may include wet etching the lower surface of the substrate using a fluorine-based etchant.

The method may further include bonding a chip-on-film to the electrode pad, wherein at least a portion of the chip-on-film may overlap the display area in a plan view, and wherein the chip-on film includes a driver for providing electrical signals to the pixel.

According to the embodiments, the electrode pads and the chip-on-film of the display device may be disposed on the rear surface of the display panel, the bezel region may be reduced, and the display area is relatively increased to satisfy design demands. Damage to the electrode pads and the peripheral layers may be prevented during the process for manufacturing the display device.

### BRIEF DESCRIPTION OF THE DRAWINGS

FIG. 1 is a schematic perspective view illustrating a use state of an electronic device according to an embodiment.

FIG. 2 is an exploded perspective view of an electronic device according to an embodiment.

FIG. 3 is a block diagram of an electronic device according to an embodiment.

FIG. 4 is a top plan view of a display device according to an embodiment.

FIG. 5 is an exploded perspective view of a display device according to an embodiment.

FIG. 6 is a cross-sectional view with respect to a line III-III′ of FIG. 1.

FIG. 7 is a cross-sectional view of a base layer according to an embodiment.

FIG. 8 is an enlarged cross-sectional view of a region A of FIG. 6.

FIG. 9 is a cross-sectional view of a pixel layer according to an embodiment.

FIG. 10 to FIG. 15 are sequential cross-sectional views of a process for manufacturing a display device according to an embodiment.

FIG. 16 is a block diagram of an electronic device according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

The drawings and description are to be regarded as illustrative in nature and not restrictive, and like reference numerals designate like elements throughout the specification.

It should be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned “on” or “above” the upper side of the object portion based on a gravitational direction.

Unless explicitly described to the contrary, the word “comprise,” and variations such as “comprises” or “comprising,” should be understood to imply the inclusion of stated elements but not the exclusion of any other elements.

The phrase “on a plane” means viewing the object portion from the top, and the phrase “in a cross-section” means viewing a cross-section of which the object portion is vertically cut from the side.

At least one embodiment of the disclosure provides a display device, an electronic device including the display device and a method of manufacturing the display device that enables a reduced bezel region and enhanced protection of electrode pads and peripheral layers during fabrication. This is achieved by forming electrode pads below a base layer on a substrate and exposing them through an opening in the substrate. In particular embodiment, the lateral surface of the substrate defining the opening includes recess portions, which enhance mechanical stability, manufacturing reliability, and pad protection during wet etching and chip-on-film (COF) bonding. In a further embodiment, the electrode pads and COF are positioned on the rear surface of the display panel, allowing the front area to be fully dedicated to display, thereby maximizing screen area while maintaining durability.

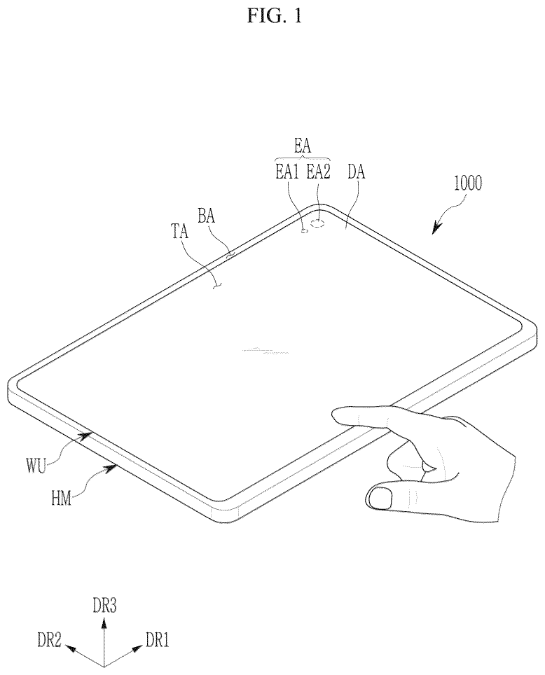

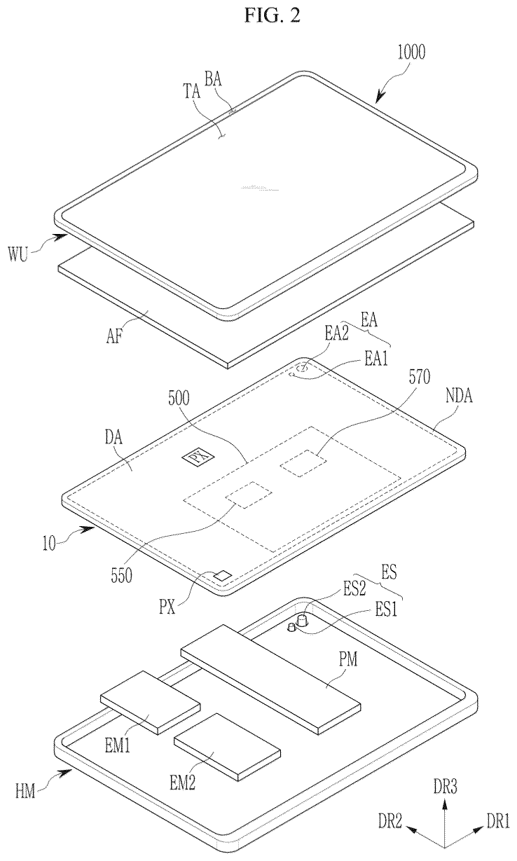

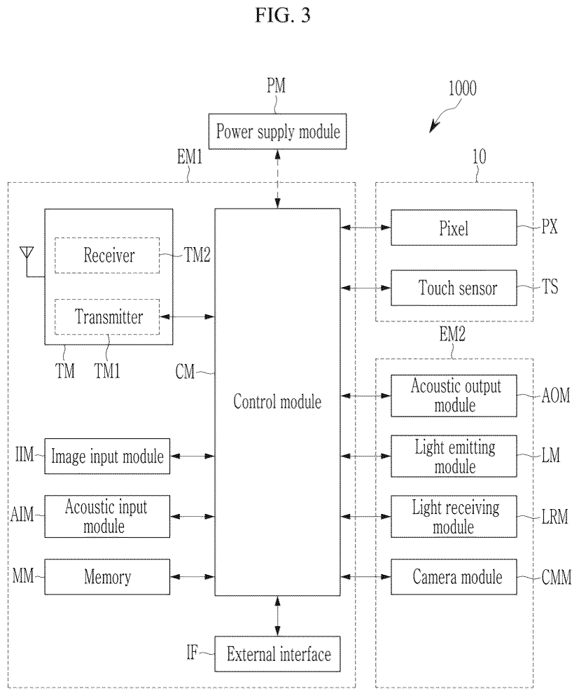

An electronic device according to an embodiment will be described with reference to FIG. 1 to FIG. 3. FIG. 1 is a perspective view of a use state of an electronic device according to an embodiment, FIG. 2 is an exploded perspective view of an electronic device according to an embodiment, and FIG. 3 is a block diagram of an electronic device according to an embodiment.

Referring to FIG. 1, the electronic device 1000 may display videos or still images and may be used as a displaying screen for various types of products such as televisions, laptops, monitors, billboards, or Internet of Things (IOT) in addition to portable electronic devices such as mobile phones, smartphones, tablet PCs, smart watches, watch phones, mobile communication terminals, digital organizers, electronic books, portable multimedia players (PMP), global positioning systems, or ultramobile PCs (UMPC). In FIG. 1, for better comprehension and ease of description, the electronic device 1000 is used as a tablet PC.

The electronic device 1000 may display images on a display surface that extends along a first direction DR1 and a second direction DR2, and faces a third direction DR3.

The display surface for displaying images may correspond to a front surface of the electronic device 1000, and may correspond to a front surface of a cover window WU. The image may include videos and still images.

In the present embodiment, the front surfaces (or upper surfaces) and the rear surfaces (or lower surfaces) of members may be defined with respect to the direction in which images are displayed. The front surfaces and the rear surfaces may oppose each other in the third direction DR3, and normal-line directions of the front surface and the rear surface may be parallel to the third direction DR3. A spaced distance between the front surface and the rear surface of the member in the third direction DR3 may correspond to the thickness of the corresponding member of the display panel in the third direction DR3.

The electronic device 1000 may sense an input (refer to the hand of FIG. 1) of a user applied from outside. The input of the user may include various forms of external inputs such as parts of the user's body, light, heat, or pressure. In an embodiment, the input of the user is shown as the user's hand applied to the front surface. However, the present disclosure is not limited to this and may be provided in various forms. The electronic device 1000 may sense inputs of the user applied to various positions such as the lateral surface (e.g., sides) or the rear surface of the electronic device 1000 according to the structure of the electronic device 1000.

Referring to FIG. 1 and FIG. 2, the electronic device 1000 may include a cover window WU, a housing HM, a display device 10, an optical member AF, an optical element ES, electronic modules EM1 and EM2 (e.g., electronic circuits), and a power supply module (PM) (e.g., a power supply or power supply circuit). In an embodiment, the cover window WU and the housing HM may be combined to form an exterior of the electronic device 1000.

The cover window WU may include an insulation panel. For example, the cover window WU may be made of glass, plastic, or combinations thereof.

A front surface of the cover window WU may define the front surface of the electronic device 1000. A transmission area TA of the cover window WU may be an optically transparent region. For example, the transmission area TA may have visible ray transmittance of more than about 90%.

A blocking area BA of the cover window WU may define a shape of the transmission area TA. The blocking area BA may be disposed near the transmission area TA and may surround the transmission area TA. The blocking area BA may have relatively lower light transmittance than the transmission area TA. The blocking area BA may include an opaque material for blocking light. The blocking area BA may have a predetermined color. The blocking area BA may be defined by a bezel layer that is separately added to a transparent substrate defining the transmission area TA, or may be defined by an ink layer embedded in or printed on the transparent substrate.

The display device 10 may include a front surface including a display area DA and a non-display area NDA. The display area DA may emit light by operating pixels according to electrical signals.

In an embodiment, the display area DA may include pixels and displays images, may have a touch sensor disposed on an upper portion in the third direction DR3 of the pixel, and may sense external inputs.

The transmission area TA of the cover window WU may at least partially overlap the display area DA of the display device 10. For example, the transmission area TA may overlap the front surface of the display area DA, or may overlap at least a portion of the display area DA. Hence, the user may view images through the transmission area TA or interact with the device by providing external inputs in response to the displayed images. However, the present disclosure is not limited thereto, and the region for displaying images may be separate from the region for sensing external inputs in the display area DA.

The non-display area NDA of the display device 10 may at least partially overlap the blocking area BA of the cover window WU. The non-display area NDA may be covered by the blocking area BA. The non-display area NDA may be disposed near the display area DA, and may surround the display area DA. The non-display area NDA does not display images and driving circuits or driving wires for driving the display area DA may be disposed in the non-display area NDA.

The display device 10 may include a component area EA that includes a first component area EA1 and a second component area EA2. The first component area EA1 and the second component area EA2 may be at least partially surrounded by the display area DA. While the first component area EA1 and the second component area EA2 are shown to be spaced apart from each other, they may be at least partially connected to each other in other embodiments. Components that operate using infrared light, visible light, or sound may be positioned beneath the first component area EA1 and the second component area EA2.

The display area DA of the display device 10 may include pixels PX. Each pixel PX may, for example, include at least one light emitting diode, and a pixel circuit for generating a light emitting current and transmitting the same to the light emitting diode.

The first component area EA1 may include a transmitting portion through which light or/and sound may be transmitted and a display unit including pixels. The transmitting portion is disposed between adjacent pixels and is made of a layer for transmitting light or/and sound. The transmitting portion may be disposed between adjacent pixels, and depending on embodiments, a layer through which light is not transmitted, such as a light blocking member, may overlap the first component area EA1. The number of pixels (also referred to as resolution) per unit area of pixels (referred to as normal pixels) included in the display area DA may correspond to the number of pixels per unit area of pixels (also referred to as first component pixels) included in the first component area EA1.

The second component area EA2 may include a region (also referred to as a light transmitting region) made of a transparent layer that allows light to pass through. No conductive or semiconductor layers are disposed in the light transmitting region. Any light blocking material, such as a pixel defining layer and/or a light blocking member may include an opening aligned with the second component area EA2, thereby allowing light to pass without obstruction. The number of pixels per unit area of pixels (also referred to as second component pixels) included in the second component area EA2 may be fewer than the number of pixels per unit area of normal pixels included in the display area DA. As a result, resolution of the second component area EA2 may be lower than that of the normal display area, which includes normal pixels.

Referring to FIG. 1, FIG. 2, and FIG. 3, the display device 10 may further include a touch sensor TS in addition to the display area DA including pixels PX. The display device 10 may include pixels PX for generating images and may be visible to the user from the outside through the transmission area TA. The touch sensor TS may be disposed on an upper portion of the display area DA, and may sense inputs applied from the outside.

The display device 10 may further include a chip-on-film 500, a driver 550 (e.g., a driver circuit), and a controller 570 (e.g., a controller circuit). Each of the driver 550 and the controller 570 may be provided as an integrated chip. The driver 550 may be mounted on the chip-on-film 500, on a separate circuit board within the display device 10, or in various locations such as in the non-display area NDA of the display device 10.

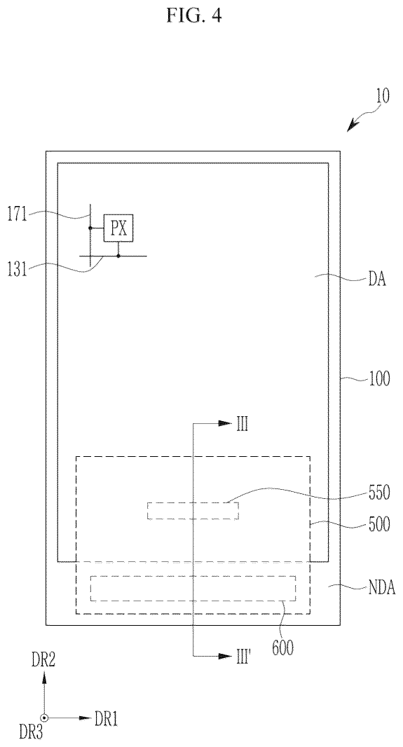

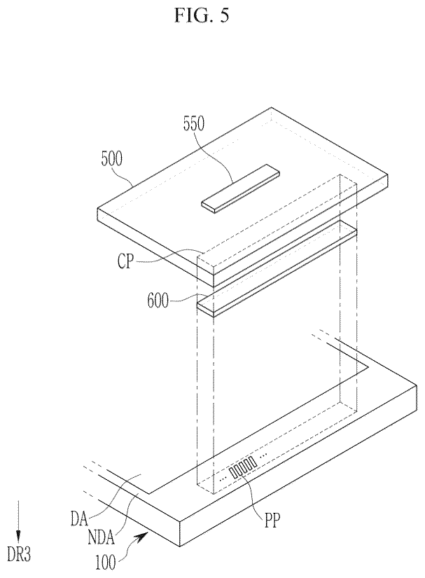

The driver 550 may be electrically connected to the display area DA and may transmit electrical signals to the display area DA. For example, the driver 550 may provide data signals to the pixels PX disposed in the display area DA. Alternatively, the driver 550 may further include a touch driving circuit, and may be electrically connected to the touch sensor TS disposed in the display area DA. A detailed description of the driver 550 will be given later with reference to FIG. 4 and FIG. 5.

The controller 570 may control general operation of the electronic device 1000. For example, the controller 570 may control operations of the pixels PX and the touch sensor TS of the display device 10. The controller 570 may control operations of the electronic modules EM1 and EM2. The controller 570 may include at least one microprocessor. The controller 570 may transmit image data and control signals to the driver 550. The control signal may include, for example, input vertical synchronization signals, input horizontal synchronization signals, main clock signals, and data enable signals.

The optical member AF may be disposed on the display device 10 in the third direction DR3. The optical member AF may include various embodiments for reducing reflectance of external light. For example, the optical member AF may include a polarization film including a retarder and/or a polarizer, multi-layered reflecting layers for offsetting and interfering reflected light, or color filters disposed corresponding to arrangement of the pixels PX of the display device 10 and light emitting colors.

The optical element ES may be disposed on a lower portion of the display device 10. The optical element ES may include a first optical element ES1 overlapping the first component area EA1 and a second optical element ES2 overlapping the second component area EA2.

The first optical element ES1 may be an electronic element that operates using light or sound. For example, the first optical element ES1 may be a sensor that receives and uses light like an infrared sensor, a sensor that outputs and senses light or sound to measure a distance or recognize fingerprints, a small lamp that outputs light, or a speaker that outputs sound.

The second optical element ES2 may be at least one of a camera, an infrared camera (IR camera), a dot projector, an infrared illuminator, and a time-of-flight sensor (ToF sensor).

Referring to FIG. 3, the electronic modules EM1 and EM2 may include a first electronic module EM1 and a second electronic module EM2. The display device 10, the power supply module (PM), the first electronic module EM1, and the second electronic module EM2 may be electrically connected to each other. FIG. 3 shows the pixel PX and the touch sensor TS disposed in the display area DA from among elements of the display device 10.

The power supply module (PM) may supply power voltages for the general operation of the electronic device 1000. The power supply module (PM) may include a battery module.

The first electronic module EM1 and the second electronic module EM2 may include various functional modules for operating the electronic device 1000. The first electronic module EM1 may be mounted on a motherboard electrically connected to the display device 10, or may be mounted on an additional substrate and may be electrically connected to the motherboard through a connector.

The first electronic module EM1 may include a control module CM, a wireless communication module TM, an image input module IIM, an acoustic input module AIM, a memory MM, and an external interface IF. Some of the modules may not be mounted on the motherboard, and may be electrically connected to the motherboard through a flexible printed circuit board connected thereto.

The control module CM may control the general operation of the electronic device 1000. The control module CM may be a microprocessor. For example, the control module CM may activate and deactivate the display device 10. The control module CM may control the image input module IIM or the acoustic input module AIM based on the touch signal received from the display device 10.

The wireless communication module TM may transmit/receive radio signals to/from other terminals by using Bluetooth or Wi-Fi lines. The wireless communication module TM may transmit and receive voice signals by using general communication lines. The wireless communication module TM includes a transmitter TM1 for modulating signals and transmitting the signals, and a receiver TM2 for demodulating the received signals.

The image input module IIM may process video signals to convert them into image data for display on the display device 10. The acoustic input module AIM may receive external acoustic signals from a microphone in a recording mode or a voice recognition mode and may convert them into electrical voice data.

The external interface IF may function as an interface connected to an external charger, a wired/wireless data port, and a card socket (e.g., a memory card, a SIM/UIM card), etc.

The second electronic module EM2 may include an acoustic output module AOM, a light emitting module LM, a light receiving module LRM, and a camera module CMM, and at least some thereof may be disposed as optical elements ES on a rear surface of the display device 10 as shown in FIG. 1 and FIG. 2. The optical element ES may include the light emitting module LM, the light receiving module LRM, and the camera module CMM. The second electronic module EM2 may be mounted on the motherboard, may be mounted on an additional substrate, may be electrically connected to the display device 10 through a connector, or may be electrically connected to the first electronic module EM1.

The acoustic output module AOM may convert the acoustic data received from the wireless communication module TM or the acoustic data retrieved from the memory MM, and output the resulting sound to the outside.

The light emitting module LM may generate and output light. The light emitting module LM may output infrared light. For example, the light emitting module LM may include an LED element. For example, the light receiving module LRM may sense infrared light. The light receiving module LRM may be activated when the infrared rays above a predetermined level are sensed. The light receiving module LRM may include a Complementary Metal-Oxide-Semiconductor (CMOS) sensor. The infrared light generated by the light emitting module LM may be output and reflected by an external object (e.g., finger or face of the user), and the reflected infrared light may be input to the light receiving module LRM. The camera module CMM may photograph external images.

In an embodiment, the optical element ES may further include a photosensor or a heat sensor. The optical element ES may sense an external object received through the front surface or may provide sound signals such as voice to the outside through the front surface. The optical element ES is not necessarily a single, monolithic part, but may be composed of multiple functional elements or components, depending on the design.

Referring to FIG. 2, the housing HM may be coupled with the cover window WU. The cover window WU may be disposed on the front surface of the housing HM. The housing HM may be coupled with the cover window WU and may provide a predetermined receiving space. The display device 10 and the optical element ES may be accommodated in the predetermined receiving space formed between the housing HM and the cover window WU.

The housing HM may include a material with relatively high rigidity. For example, the housing HM may include glass, plastic, or metal, or may include frames and/or plates formed by combinations thereof. The housing HM may stably protect the components of the electronic device 1000 housed in the internal space from external impacts.

A display device according to an embodiment will be described with reference to FIG. 4 and FIG. 5. FIG. 4 is a top plan view of a display device according to an embodiment. FIG. 5 is an exploded perspective view of a display device according to the embodiment shown in FIG. 4.

Referring to FIG. 4 and FIG. 5, the display device 10 may include a display panel 100, the chip-on-film 500, and an adhesive member 600 for connecting the display panel 100 and the chip-on-film 500.

The display panel 100 may be an organic light emitting panel including organic light emitting elements or a liquid crystal panel including a liquid crystal layer, but is not limited thereto.

A plurality of signal lines and pixels PX connected to the signal lines are disposed in the display area DA of the display panel 100. The plurality of signal lines include a gate line 131 and a data line 171. The gate line 131 may substantially extend in a row direction (or horizontal direction), and the data line 171 may substantially extend in a column direction (vertical direction). The pixels PX may be connected to the gate line 131 and the data line 171, and may receive a gate signal and a data signal from the signal lines. The pixels PX are disposed on a plane parallel to the first direction DR1 and the second direction DR2. The direction that is perpendicular to or intersecting the first direction DR1 and the second direction DR2 may be referred to as the third direction DR3, and the display panel 100 may include layers mainly stacked in the third direction DR3.

Depending on embodiments, signal lines disposed in the display area DA of the display panel 100 may further include a driving voltage line for transmitting a driving voltage (ELVDD) and a common voltage line for transmitting a common voltage (ELVSS). The signal lines may further include a previous-stage gate line for transmitting a previous-stage scan signal, an emission control line for transmitting an emission control signal, a bypass control line for transmitting a bypass signal, and an initialization voltage line for transmitting an initialization voltage.

When the display panel 100 is an organic light emitting panel, the pixels PX may include transistors, storage capacitors, and organic light emitting elements. For example, the transistors may include a driving transistor, a switching transistor, and a compensation transistor.

The driving transistor, the switching transistor, and the compensation transistor may include a gate electrode, a source electrode, and a drain electrode.

The driving transistor includes the gate electrode connected to a first electrode of the storage capacitor, the source electrode connected to a driving voltage line, and the drain electrode electrically connected to an anode of the organic light emitting element. The driving transistor may receive a data signal, and may supply a driving current to the organic light emitting element according to a switching operation of the switching transistor.

The switching transistor may include the gate electrode connected to the gate line 131, the source electrode connected to the data line 171, and the drain electrode connected to the source electrode of the driving transistor and the driving voltage line.

The switching transistor may be turned on by the gate signal received through the gate line 131, and may perform a switching operation for transmitting the data signal transmitted through the data line 171 to the source electrode of the driving transistor.

The compensation transistor includes the gate electrode connected to the gate line, the source electrode connected to the drain electrode of the driving transistor and an anode of the organic light emitting element, and the drain electrode connected to a first electrode of the storage capacitor and the gate electrode of the driving transistor. The compensation transistor may be turned on by the gate signal received through the gate line 131, and may connect the gate electrode and the drain electrode of the driving transistor to diode-connect the driving transistor.

The storage capacitor may include a first and second electrodes facing each other. The second electrode of the storage capacitor may be connected to the driving voltage line, and the cathode of the organic light emitting element may be connected to the common voltage line.

The organic light emitting element may include an anode that is a hole injection electrode, a cathode that is an electron injection electrode, and an organic light emitting layer. In the organic emission layer, excitons, formed by the combinations of holes injected from the anode and electrons injected from the cathode, release energy as light when transitioning from an excited state to a ground state.

Electrode pads PP for receiving signals from the outside of the display panel 100 may be disposed in the non-display area NDA of the display panel 100. The electrode pads PP may be electrically connected to the signal lines disposed in the display area DA. A gate driver may be integrated in the non-display area NDA of the display panel 100, and the gate driver may be provided as an integrated circuit chip depending on embodiments.

The chip-on-film 500 may be bent, and may include a driver 550 and connection pads CP.

The driver 550 may generate a data voltage, which is a grayscale voltage corresponding to input video signals. The driver 550 may be mounted on the chip-on-film 500 and may be connected as a tape carrier package TCP to the connection pads CP.

The connection pads CP may be disposed on a side of an end of the chip-on-film 500. The connection pads CP may be electrically connected to the electrode pads PP of the display panel 100 through the adhesive member 600.

The adhesive member 600 may be disposed between the electrode pads PP of the display panel 100 and the connection pads CP of the chip-on-film 500. The adhesive member 600 may include a conductive ball having a spherical shape. One of the electrode pads PP of the display panel 100 and one of the connection pads CP of the chip-on-film 500 may be conducted by at least one conductive ball. The display panel 100 may receive signals from the chip-on-film 500.

Referring to FIG. 4 and FIG. 5, the region where the electrode pads PP and the connection pads CP are bonded by the adhesive member 600 is disposed on the rear surface of the display panel 100. The chip-on-film 500 may be disposed on the rear surface of the display panel 100, such that it is not connected from the front side of the panel, thereby reducing the area of the non-display area NDA. Further, the chip-on-film 500 may overlap the display area DA in a plan view, contributing to an even further reduction of the non-display area NDA. Hence, the display area DA may be relatively expanded, and the bezel region of the non-display area NDA minimized, meeting the design demands of the display device.

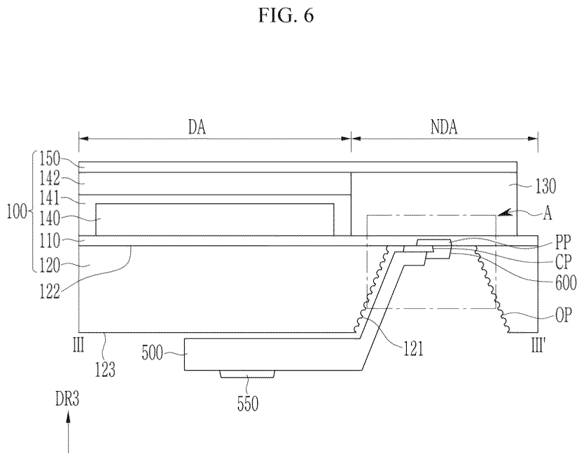

Structures of the display panel 100, the electrode pads PP, and the chip-on-film 500 will be described, focusing on the cross-sectional view of the display device according to an embodiment with reference to FIG. 6 to FIG. 8.

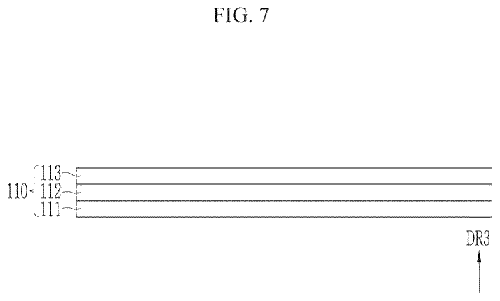

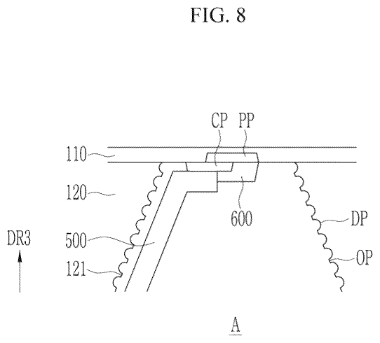

FIG. 6 is a cross-sectional view with respect to a line III-III′ of FIG. 1. FIG. 7 is a cross-sectional view of a base layer 110 according to an embodiment. FIG. 8 is an enlarged cross-sectional view of a region A of FIG. 6.

Referring to FIG. 6, the display panel 100 may include a substrate 120. The substrate 120 may include the display area DA and the non-display area NDA surrounding at least a portion of the display area DA. For example, a portion of the non-display area NDA may be adjacent to the display area DA. The substrate 120 may include a rigid material such as glass. The substrate 120 may have an opening OP overlapping the non-display area NDA. The opening OP may be a through-hole that passes entirely through the substrate 120. The substrate 120 may have a lateral surface 121 (e.g., a side surface) defining the opening OP. The lateral surface 121 may be an inclined surface that is slanted in a different direction from the third direction DR3, a planar surface that is parallel to the second direction DR2, and the first direction DR1. At least a portion of the lateral surface 121 may be a planar surface or a curved surface.

The substrate 120 may include a first surface 122 that is parallel to the first direction DR1 and the second direction DR2, and a second surface 123 facing the first surface 122. The second surface 123 may face the rear surface of the display panel 100.

The base layer 110 may be disposed on the first surface 122 of the substrate 120. The base layer 110 may include an inorganic insulating material such as silicon nitride (SiNₓ), amorphous silicon, and silicon oxide (SiOₓ).

Referring to FIG. 7, the base layer 110 may be a multilayer. For example, the base layer may include a first layer 111 including silicon nitride, a second layer 112 including amorphous silicon, and a third layer 113 including silicon oxide. The first layer 111 may contact the first surface 122 of the substrate 120, the second layer 112 may be disposed on the first layer 111, and the third layer 113 may be disposed on the second layer 112. Referring to FIG. 6 and FIG. 7, the opening OP of the substrate 120 may expose a portion of the first layer 111. The first layer 111 and the second layer 112 may prevent damage to the components disposed on the upper portion of the base layer 110 when exposed to an etchant. For example, the etchant may be a fluorine-based etchant, which is used in an etching process for forming the opening OP of the substrate 120. The first layer 111 and the third layer 113 may prevent current leakage between elements on the upper portion of the base layer 110 and the electrode pads PP.

The electrode pads PP may be disposed below the surface contacting the first surface 122 of the substrate from among the surfaces of the base layer 110. The electrode pads PP overlap the non-display area NDA, and the opening OP of the substrate 120 exposes the electrode pads PP.

The electrode pads PP may include a metal such as tungsten (W), molybdenum (Mo), or chromium (Cr), or metal alloys thereof. The electrode pads PP may be a single layer or a multilayer. For example, each of the electrode pads PP may include a first metal layer and a second metal layer, and the first metal layer may include at least one of tungsten and chromium. The opening OP of the substrate 120 may expose the first metal layer. Hence, the electrode pads PP should not become corroded when exposed to an etchant. For example, the etching process for forming the opening OP of the substrate 120 may use a fluorine-based etchant.

Referring to FIG. 6, the chip-on-film 500 may be electrically connected to the electrode pads PP on the rear surface of the base layer 110. The connection pads CP disposed on an end portion of the chip-on-film 500 may be bonded to the electrode pads PP through the adhesive member 600. The chip-on-film 500 may extend from the connection pads CP to the second surface 123 of the substrate 120 along the lateral surface 121 of the substrate 120. The chip-on-film 500 may be bent at a border of the lateral surface 121 and the second surface 123 and may overlap the display area DA in a plan view on the second surface 123. For example, the chip-on-film 500 may include horizontal portion in the display area DA and a slanted portion in the non-display area NDA that is aligned with a slant of the opening OP and connects to the connection pads CP and to the horizontal portion. Hence, the area of the non-display area NDA may be reduced, resulting in a relative increase in the physical area of the display area DA.

Referring to FIG. 6 and FIG. 8, in an embodiment, the lateral surface 121 of the substrate 120 includes recess portions DP (e.g., indented regions, grooved portions, depressed sections). The recess portions DP may respectively have a depth of about 0.4 um to 4 um in the direction that is perpendicular to the direction in which the lateral surface 121 extends. Hence, the lateral surface 121 may have the recess portions DP and corresponding convex portions to thus have an uneven structure. For example, the lateral surface 121 may include the recess portions DP along with corresponding raised areas, resulting in an uneven or textured structure. The lateral surface 121 may include alternating recess portions DP and flat regions. When surface roughness of the lateral surface 121 is proportional to the depth and number of the recess portions DP, the surface roughness of the lateral surface 121 of the substrate 120 is greater than the surface roughness of the second surface 123.

Referring to FIG. 6, a pixel layer 140 overlapping the display area DA may be disposed on the first surface 122 of the substrate 120. The pixel layer 140 may include pixels. The pixels may include transistors, storage capacitors, and light emitting elements. The pixel layer 140 may include at least one conductive layer and at least one insulation layer.

A sealing layer 141 for covering and sealing the pixel layer 140 may be disposed on the pixel layer 140. The sealing layer 141 may include at least one inorganic film and at least one organic film.

A sensing electrode layer 142 may be disposed on the sealing layer 141. The sensing electrode layer 142 may include sensing electrodes. The sensing electrodes may include first sensing electrodes and second sensing electrodes electrically separated from each other. The first sensing electrodes may be sensing input electrodes, and the second sensing electrodes may be sensing output electrodes. The first sensing electrodes and the second sensing electrodes may be disposed on the same conductive layer or on different conductive layers. At least one sensing insulation layer may be disposed between the first sensing electrode and the second sensing electrode.

A planarization layer 130 overlapping the non-display area NDA may be disposed on the first surface 122 of the substrate 120. The planarization layer 130 may planarize surfaces of the non-display area NDA and the display area DA on the first surface 122 of the substrate 120. The planarization layer 130 may be near the sealing layer 141 in the direction that is perpendicular to the third direction DR3. The planarization layer 130 may be an organic insulator including at least one insulating material such as polyimide, polyamide, acryl resin, benzocyclobutene and phenol resin.

A polarization layer 150 may be disposed on the sensing electrode layer 142 and the planarization layer 130. The polarization layer 150 may prevent deterioration of display quality as the user sees light reflected from an internal element by incident external light.

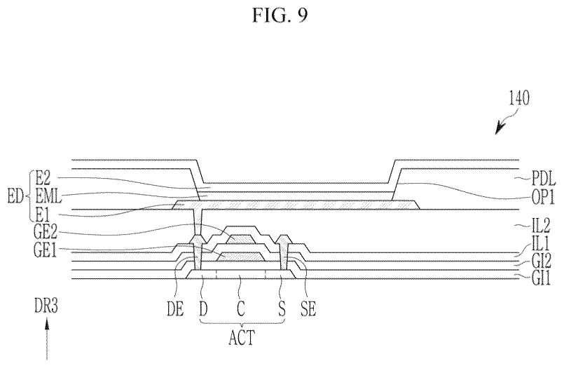

A structure of the pixel layer 140 according to an embodiment will be described with reference to FIG. 9. FIG. 9 is a cross-sectional view of the pixel layer 140 according to an embodiment.

A semiconductor layer ACT of FIG. 9 may be disposed on the first surface 122 of the substrate 120 of FIG. 6. Depending on embodiments, at least one insulation layer may be disposed between the substrate 120 and the semiconductor layer ACT.

The semiconductor layer ACT may include one of amorphous silicon, polycrystalline silicon, and an oxide semiconductor. For example, the semiconductor layer ACT may include low-temperature polysilicon LTPS or may include an oxide semiconductor including at least one of zinc (Zn), indium (In), gallium (Ga), tin (Sn), and mixtures thereof. The semiconductor layer ACT may include a channel region C, a source region S, and a drain region D distinguished by whether they are doped with impurities. The source region S and the drain region D may have conductive characteristic that corresponds to a conductor.

A first gate insulation layer GI1 may be disposed on the semiconductor layer ACT. The first gate insulation layer GI1 may cover the semiconductor layer ACT and the substrate 120. The first gate insulation layer GI1 may include an inorganic insulating material such as silicon nitride (SiNx), silicon oxide (SiOx), or silicon oxynitride (SiOxNy). The first gate insulation layer GI1 may be a single layer or a multilayer including the above-described inorganic insulating material.

A gate electrode GE1 may be disposed on the first gate insulation layer GI1. The gate electrode GE1 may include a metal such as copper (Cu), molybdenum (Mo), aluminum (Al), silver (Ag), chromium (Cr), tantalum (Ta), or titanium (Ti), and metal alloys thereof. The gate electrode GE1 may be a single layer or a multilayer. The channel region C may be the region overlapping the in-plane gate electrode GE1 in the semiconductor layer ACT.

A second gate insulation layer GI2 may be disposed on the gate electrode GE1. The second gate insulation layer GI2 may include an inorganic insulating material such as silicon nitride (SiNx), silicon oxide (SiOx), or silicon oxynitride (SiOxNy). The second gate insulation layer GI2 may be a single layer or a multilayer including the above-described inorganic insulating material.

A capacitor electrode GE2 may be disposed on the second gate insulation layer GI2. The capacitor electrode GE2 may overlap the gate electrode GE1 and may form a capacitor.

A first insulation layer IL1 may be disposed on the capacitor electrode GE2. The first insulation layer IL1 may include an inorganic insulating material such as silicon nitride (SiNx), silicon oxide (SiOx), or silicon oxynitride (SiOxNy). The first insulation layer IL1 may be a single layer or a multilayer including the above-described inorganic insulating material.

The source electrode SE and the drain electrode DE may be disposed on the first insulation layer IL1. The source electrode SE and the drain electrode DE are connected to the source region S and the drain region D, respectively, of the semiconductor layer ACT by the openings formed in the first insulation layer IL1, the second gate insulation layer GI2, and the first gate insulation layer GI1. Hence, the semiconductor layer ACT, the gate electrode GE1, the source electrode SE, and the drain electrode DE form one transistor. According to an embodiment, a transistor TFT may include a source region and a drain region of the semiconductor layer ACT instead of the source electrode SE and the drain electrode DE.

The source electrode SE and the drain electrode DE may include a metal such as aluminum (Al), copper (Cu), silver (Ag), gold (Au), platinum (Pt), palladium (Pd), nickel (Ni), molybdenum (Mo), tungsten (W), titanium (Ti), chromium (Cr), or tantalum (Ta), and metal alloys thereof. The source electrode SE and the drain electrode DE may be a single layer or a multilayer.

A second insulation layer IL2 may be disposed on the source electrode SE and the drain electrode DE. The second insulation layer IL2 covers the source electrode SE and the drain electrode DE. The second insulation layer IL2 may planarize a surface of a substrate SUB on which transistors are mounted, it may be an organic insulator, and may include at least one insulating material such as polyimide, polyamide, acryl resin, benzocyclobutene, and phenol resin.

The first electrode E1 may be disposed on the second insulation layer IL2. The first electrode E1 may be referred to as an anode, and may be made of a single layer including a transparent conductive oxide layer or a metallic material, or a multilayer. The transparent conductive oxide layer may include indium tin oxide (ITO), poly-ITO, indium zinc oxide (IZO), indium gallium zinc oxide (IGZO), and indium tin zinc oxide (ITZO). The metallic material may include at least one of silver (Ag), molybdenum (Mo), copper (Cu), gold (Au), and aluminum (Al).

The first electrode E1 may be physically and electrically connected to the drain electrode DE through an opening in the second insulation layer IL2. Hence, the first electrode E1 may receive an output current to be transmitted to the light emitting layer EML from the drain electrode DE.

A pixel defining layer PDL may be disposed on the first electrode E1 and the second insulation layer IL2. The pixel defining layer PDL includes a pixel opening OP1 overlapping at least a portion of the first electrode E1

The pixel opening OP1 may overlap a center portion of the first electrode E1, and may not overlap an edge of the first electrode E1. The pixel defining layer PDL may partition a forming position of the light emitting layer EML so that the light emitting layer EML may be disposed on the exposed portion of the upper surface of the first electrode E1. For example, the pixel defining layer PDL may define the formation region of the light emitting layer EML, allowing it to be disposed on the exposed central portion of the upper surface of the first electrode E1.

The pixel defining layer PDL may be an organic insulator including at least one selected from a group consisting of polyimide, polyamide, acryl resin, benzocyclobutene, and phenol resin, and depending on embodiments, the pixel defining layer PDL may be made of a black pixel defining layer (BPDL) including a black color pigment.

The light emitting layer EML may be disposed in the pixel opening OP1 partitioned by the pixel defining layer PDL. The light emitting layer EML may include organic materials for emitting red, green, and blue light. The light emitting layer EML may include a low-molecular or polymer organic material. Auxiliary layers such as an electron injection layer, an electron transport layer, a hole transport layer, and a hole injection layer may be included above and below the light emitting layer EML, wherein the hole injection layer and the hole transport layer are disposed on the lower portion of the light emitting layer EML, and the electron transport layer and the electron injection layer are disposed on the upper portion of the light emitting layer EML. According to an embodiment, the light emitting layer EML may include a quantum dot including semiconductor nanocrystals.

The second electrode E2 may be disposed on the pixel defining layer PDL and the light emitting layer EML. The second electrode E2 may be referred to as a cathode. The second electrode E2 may be made of a transparent conductive layer including at least one of indium tin oxide (ITO), indium zinc oxide (IZO), indium gallium zinc oxide (IGZO), and indium tin zinc oxide (ITZO). The second electrode E2 may have a semi-transparent characteristic, and may form a microcavity together with the first electrode E1. According to the microcavity structure, light with a specific wavelength may be emitted upward due to the optical resonance formed by the gap between the electrodes and the transparency of the second electrode E2, thereby enabling the display of red, green, and blue colors. The first electrode E1 may have a reflective characteristic.

The first electrode E1, the light emitting layer EML, and the second electrode E2 may form a light emitting element ED.

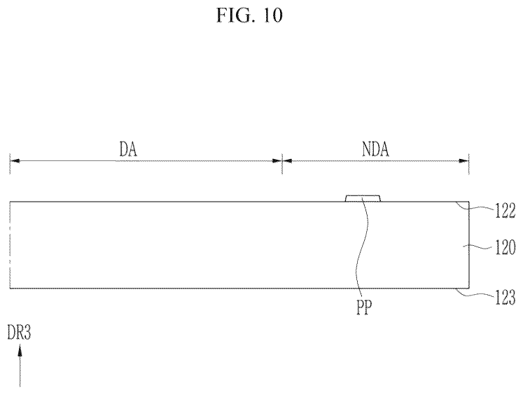

A method for manufacturing a display device according to an embodiment will be described with reference to FIG. 10 to FIG. 15 together with the above-described drawings. FIG. 10 to FIG. 15 are sequential cross-sectional views of a process for manufacturing a display device according to an embodiment. The same components as the above-described components will not be described.

Referring to FIG. 10, the electrode pads PP are formed on the first surface 122 of the substrate 120. The electrode pads PP may overlap the non-display area NDA. The electrode pads PP may be aligned in a row in the first direction DR1 or the second direction DR2, and FIG. 5 shows them disposed in the first direction DR1. The electrode pads PP may include a metal such as tungsten (W), molybdenum (Mo), or chromium (Cr), or metal alloys thereof. Each of the electrode pads PP may include a first metal layer and a second metal layer. For example, the first metal layer including at least one of tungsten and chromium may be formed on the first surface 122 of the substrate 120, and the second metal layer may be formed on the first metal layer.

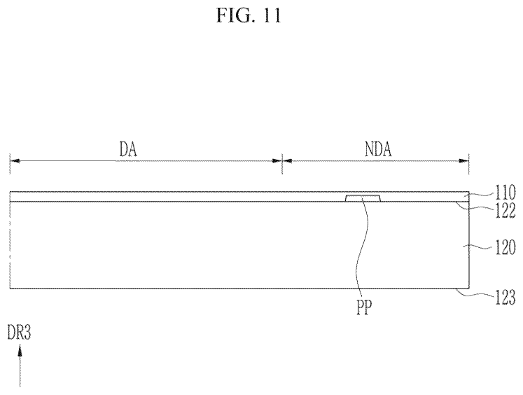

Referring to FIG. 11, the base layer 110 is stacked on the first surface 122 of the substrate 120 and the electrode pads PP. The base layer 110 may include a first layer, a second layer, and a third layer. For example, the first layer including silicon nitride may be stacked on the first surface 122 of the substrate 120. The second layer including amorphous silicon may be stacked on the first layer. The third layer including silicon oxide may be stacked on the second layer.

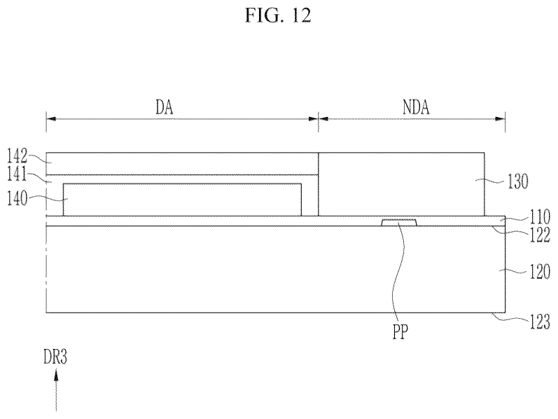

Referring to FIG. 12, the pixel layer 140 overlapping the display area DA is formed on the base layer 110. The pixel layer 140 may be formed only in the display area DA. The sealing layer 141 for covering and sealing the pixel layer 140 is formed and the sensing electrode layer 142 is formed on the sealing layer 141. The planarization layer 130 overlapping the non-display area NDA is formed on the base layer 110. The planarization layer 130 and the sealing layer 141 may be adjacent each other in the direction that is perpendicular to the third direction DR3.

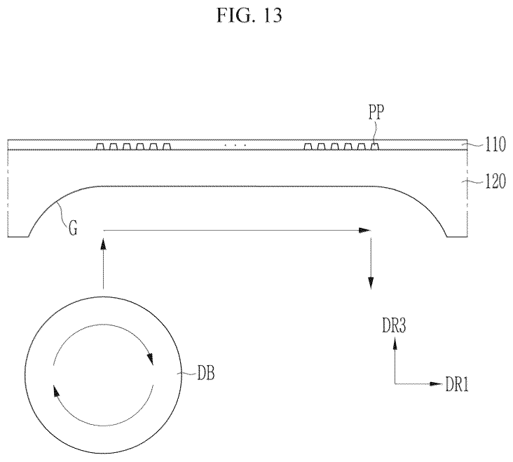

Referring to FIG. 13, a groove G overlapping the electrode pads PP is formed by patterning the second surface 123, which is the rear surface of the substrate 120. For example, a circular blade DB may rotate in the direction in which the electrode pads PP are disposed to thus form the groove G. A portion of the substrate 120 in the thickness direction may be incised by a rotational frictional force of the circular blade DB to form the groove G. FIG. 10 shows that the electrode pads PP are disposed in the first direction DR1, and the circular blade DB passes through in the first direction DR1. A depth of the groove G in the third direction DR3 may be about 0.5 to 0.6 times the thickness of the substrate 120. For example, when the thickness of the substrate in the third direction DR3 is about 400 μm, the depth of the groove may be about 203 μm to 213 μm.

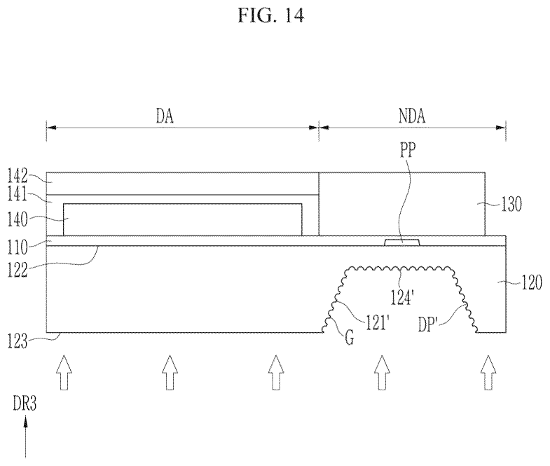

Referring to FIG. 14, recess portions DP′ are formed on an internal side of the groove G patterned by the circular blade DB. The internal side may include lateral surfaces 121′ and a bottom surface 124′ surrounded by the lateral surfaces 121′. The lateral surface 121′ may be an inclined surface that is slanted in a different direction from a planar surface that is parallel to the first direction DR1 and the second direction DR2 and the third direction DR3. At least a portion of the lateral surface 121′ may be a planar surface or a curved surface.

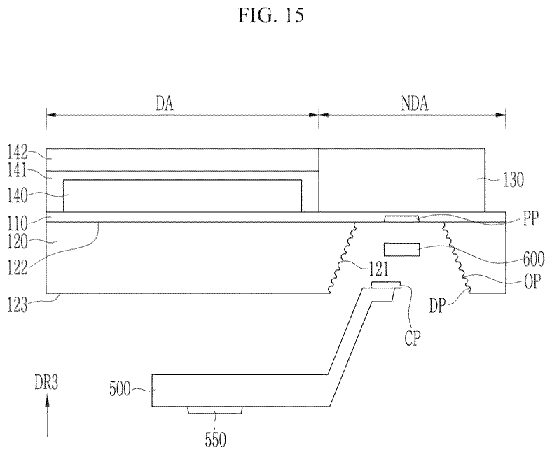

Referring to FIG. 14 and FIG. 15, the front surface of the second surface 123 of the substrate 120 including the groove G is etched (e.g., wet-etched) to form the opening OP exposing the electrode pads PP. A fluorine-based etchant such as an HF etchant may be used for performing the wet etching. The electrode pads PP include at least one of tungsten (W) and chromium (Cr) to prevent them from being corroded when exposed to the fluorine-based etchant. The base layer 110 may include at least one of silicon nitride and amorphous silicon to prevent it from being damaged even if exposed to the fluorine-based etchant. In this case, the opening OP may be formed by further extending the pre-etched groove G through wet etching, during which the inner lateral surface 121′ of the groove G is etched to form the lateral surface 121. The recess portion DP′ of the lateral surface 121′ may increase its depth by wet etching and may form the recess portions DP of the lateral surface 121. For example, the recess portion DP′ of the lateral surface 121′ may be deepened through wet etching. The depths of the recess portions DP in the direction that is perpendicular to the lateral surface 121 may be about 0.4 μm to 4 μm. The substrate 120 between the bottom surface 124′ of the groove G before wet etching and the electrode pads PP may be removed during the wet etching process.

Referring to FIG. 15, the electrode pads PP exposed through the opening OP and the connection pads CP on the chip-on-film 500 may be bonded together with the adhesive member 600 therebetween. For example, the electrode pads PP and the connection pads CP may be bonded using the adhesive member 600 through an outer lead bonding (OLB) process, thereby establishing both physical and electrical connection between them. Hence, the electrode pads PP and the connection pads CP may be physically bonded and may be connected to each other. The chip-on-film 500 may not be bent toward the second surface 123 on the first surface 122 of the substrate 120, but may be disposed on the second surface 123 along the lateral surface 121 of the opening OP of the substrate 120, so the design demands of the display device may be satisfied by reducing the bezel region, which is the non-display area NDA. For example, the chip-on-film 500 may be bent along the lateral surface 121 of the opening OP, with one portion disposed on the lateral surface 121 and another portion extending onto the second surface 123 of the substrate 120. The chip-on-film 500 may remain unbent on the second surface 123.

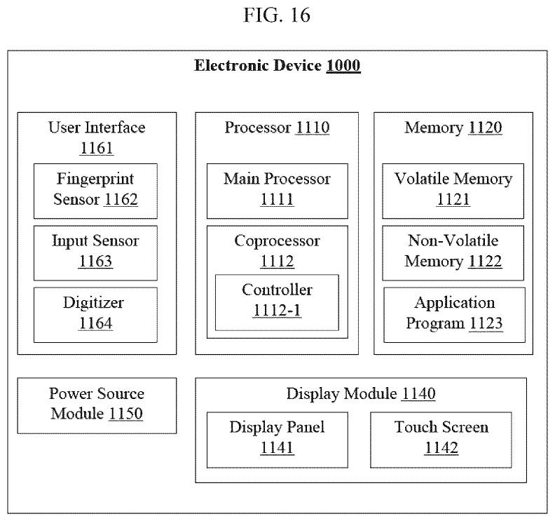

FIG. 16 is a diagram illustrating an electronic device according to an embodiment of the present invention. Referring to FIG. 16, the electronic device 1000 according to one embodiment of the present invention may output various information (e.g., images, text, music, etc.) through a display module 1140, which, for example, may correspond to the display device shown in FIG. 4. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 may be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module or the camera device. The processor 1110 may transmit image data corresponding to a captured image acquired through the camera module to the display module 1140. The display module 1140 may display an image corresponding to the captured image through the display panel 1141.

For example, the camera device may be configured to capture images of an alignment inspection area of the electronic device, where the alignment inspection area includes an alignment bump (e.g., ABP), an alignment pad (e.g., APD) bonded to the alignment bump, and an alignment polymer pattern (e.g., APP) that is spaced apart from the alignment pad; and the processor 1110 may be configured to: process the captured images to detect center positions of the alignment bump, the alignment pad, and the alignment polymer pattern; compare the detected center positions of the alignment bump and the alignment pad with the center position of the alignment polymer pattern; and determine presence of misalignment based on results of the compare.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

The memory 1120 may store instructions, that, when executed by the processor 1110, cause it to perform the above steps of processing, comparing, and determining misalignment.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The processor 1110 may provide an output signal to the user interface 1161 based on the determination of misalignment, where the output signal can be used to alert operators or activate further inspection or correction processes.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device shown in FIG. 4.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 4.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

While this disclosure has been described in connection with what is presently considered to be example embodiments, it is to be understood that the disclosure is not limited to these embodiments, but, on the contrary, is intended to cover various modifications and equivalent arrangements included within the spirit and scope of the appended claims.

What is claimed is:

1. A display device comprising:
a substrate including a display area and a non-display area that is adjacent to the display area;
a pixel overlapping the display area;
a base layer disposed on a first surface of the substrate; and
an electrode pad disposed below a surface of the base layer facing the substrate, and overlapping the non-display area,
wherein the substrate includes an opening exposing the electrode pad, and
a lateral surface of the substrate that defines the opening includes recess portions.

2. The display device of claim 1, further comprising:
a chip-on-film including a driver for providing electrical signals to the pixel,
wherein the electrode pad is electrically connected to the chip-on-film.

3. The display device of claim 2, wherein
at least a portion of the chip-on-film overlaps the display area.

4. The display device of claim 2, wherein
the chip-on-film includes a connection pad electrically connected to the electrode pad, and further includes an adhesive member disposed between the connection pad and the electrode pad.

5. The display device of claim 1, wherein
the electrode pad includes at least one of tungsten (W), molybdenum (Mo), and chromium (Cr).

6. The display device of claim 5, wherein
the electrode pad includes a first metal layer and a second metal layer,
the second metal layer includes at least one of tungsten and chromium, and
the opening exposes the second metal layer.

7. The display device of claim 1, wherein
the base layer includes at least one of silicon nitride (SiNₓ), amorphous silicon (a-Si), and silicon oxide (SiOₓ).

8. The display device of claim 7, wherein
the base layer includes a first layer including silicon nitride, a second layer including amorphous silicon, and a third layer including silicon oxide.

9. The display device of claim 8, wherein
the opening exposes a portion of the first layer.

10. The display device of claim 1, wherein
the substrate further includes a second surface facing the first surface and connected to the lateral surface, and
a surface roughness of the lateral surface is greater than a surface roughness of the second surface.

11. A method for manufacturing a display device, comprising:
forming an electrode pad in a non-display area of a substrate;
forming a base layer on the electrode pad;
forming pixels in a display area of the substrate adjacent to the non-display area;
patterning a region of a lower surface of the substrate corresponding to the electrode pad to form a groove overlapping the electrode pad; and
etching the lower surface of the substrate, including the groove, to form an opening that exposes the electrode pad.

12. The method of claim 11, wherein
a lateral surface of the substrate defining the opening includes recess portions.

13. The method of claim 11, wherein
the electrode pad includes at least one of tungsten (W), molybdenum (Mo), and chromium (Cr).

14. The method of claim 11, wherein
the forming of the base layer includes
forming a first layer including silicon nitride,
forming a second layer including amorphous silicon on the first layer, and
forming a third layer including silicon oxide on the second layer.

15. The method of claim 11, wherein
the patterning includes
forming the groove extending in a direction in which the electrode pad is aligned and overlapping the electrode pad by using a circular blade.

16. The method of claim 15, wherein
a depth of the groove is about 0.5 to 0.6 times a thickness of the substrate.

17. The method of claim 11, wherein
the etching includes wet etching the lower surface of the substrate using a fluorine-based etchant.

18. The method of claim 11, further comprising:
bonding a chip-on-film to the electrode pad,
wherein at least a portion of the chip-on-film overlaps the display area in a plan view, and
wherein the chip-on-film includes a driver for providing electrical signals to the pixel.

19. An electronic device comprising:
a cover window;
a housing coupled to the cover window; and
a display device disposed between the cover window and the housing,
wherein the display device includes
a substrate including a display area and a non-display area that is adjacent to the display area;
a pixel overlapping the display area;
a base layer disposed on a first surface of the substrate; and
an electrode pad disposed below a surface facing the substrate, and overlapping the non-display area,
wherein the substrate includes an opening exposing the electrode pad, and
a lateral surface of the substrate that defines the opening includes recess portions.

20. The electronic device of claim 19, wherein
the electrode pad includes at least one of tungsten (W), molybdenum (Mo), and chromium (Cr), and
the base layer includes a first layer including silicon nitride (SiNₓ), a second layer including amorphous silicon (a-Si), and a third layer including silicon oxide (SiOₓ).
